(19) United States
(12) Patent Application Publication
(10) Pub. No.: US 2025/0218895 A1
(43) Pub. Date: Jul. 3, 2025

(54) Integrated Circuit Package Structure with Thermelectric Self-Cooling Device

(71) Applicant: Taiwan Semiconductor Manufacturing Company, Ltd., Hsin-Chu (TW)

(72) Inventors: Chien-Chang WANG, Hsinchu City (TW); Kuan-Min WANG, Hsinchu City (TW); Bang-Li WU, Hsinchu City (TW); Kuo-Chin CHANG, Hsinchu (TW); Kathy Wei YAN, Hsinchu (TW); Jun HE, Hsinchu County (TW)

(21) Appl. No.: 18/643,788

(22) Filed: Apr. 23, 2024

Related U.S. Application Data
(60) Provisional application No. 63/615,603, filed on Dec. 28, 2023.

(51) Int. Cl. H01L 23/473; H01L 23/00; H01L 23/367; H01L 23/38; H01L 25/18

(52) U.S. Cl. CPC H01L 23/473; H01L 23/367; H01L 23/38; H01L 24/08; H01L 24/16; H01L 25/18; H01L 2224/08145; H01L 2224/16225; H01L 2225/06517; H01L 2225/06589; H01L 2924/1815

(57) ABSTRACT

The present disclosure provides an integrated circuit (IC) structure that includes an IC packaging structure having an IC chip; and a thermoelectric self-cooling device (TESCD) integrated with the IC packaging structure. The TESCD further includes a thermoelectric cooling (TEC) device having a plurality of TEC units configured in an array and electrically connected to provide cooling effect to the IC packaging structure, and a liquid cooling module having a cooling liquid driving device and a generator coupled with the cooling liquid driving device to collectively generate an electrical power supplied to the TEC device with self-cooling function to the IC packaging structure.

### PRIORITY DATA

This application claims priority to U.S. Provisional Patent Application Ser. No. 63/615,603 filed on Dec. 28, 2023, the entire disclosure of which is hereby incorporated herein by reference.

### BACKGROUND

Many of the technological advances have occurred in the field of a three-dimensional IC (3DIC) packaging, which involves stacking and bonding multiple chips together. Each chip includes at least one functional IC, such as an IC configured to perform a logic function, a memory function, a digital function, an analog function, a mixed signal function, a radio frequency (RF) function, a input/output (I/O) function, a communications function (e.g., provides support for wired communications and/or wireless communications by implementing desired communication protocols, such as 5G (i.e., 5th generation) wireless communications protocols, Ethernet communications protocols, IB communications protocols, etc.), a power management function, other function, or combinations thereof. memory devices, and some of these involve capacitors. With continued advances in 3DIC stacking technology, integrated chips may experience various issues including thermal dissipation, which may further cause other issues, such as bonding, stressing and delamination issues, and reliability issues. On other aspects, as multi-gate devices are used for advanced IC structures and continue to scale, challenges have arisen in some areas including current leakage and thermal dissipation issue, especially when the IC structures have high current, high voltage or high speed. Therefore, while existing IC structures, and the method making the same are generally adequate for their intended purposes, they are not satisfactory in all aspects.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1 illustrates a sectional or schematic view of an integrated circuit (IC) structure having a thermoelectric self-cooling device (TESCD) constructed according to some embodiments.

FIG. 2 illustrates a sectional view of the IC structure in FIG. 1, in portion, constructed according to some embodiments.

FIG. 3 illustrates a top view of the IC structure in FIG. 1, in portion, constructed according to some embodiments.

FIG. 4 illustrates a sectional or schematic view of an IC structure having a TESCD constructed according to some embodiments.

FIGS. 5A, 5B and 5C illustrates top views of the IC structure in FIG. 1, in portion, constructed according to various embodiments.

FIG. 6 illustrates a sectional or schematic view of an IC structure having a TESCD constructed according to some embodiments.

FIGS. 7A, 7B, 7C, 7D, 7E and 7F illustrate top views of the IC structure in FIG. 1, in portion, constructed according to various embodiments.

FIG. 8 illustrates a sectional view of the IC structure in FIG. 1, in portion, constructed according to some embodiments.

FIG. 9 illustrates a flowchart of method making the IC structure in FIG. 1, in portion, constructed according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

The present disclosure relates to an integrated circuit (IC) structure and a method of making the same. More specifically, the present disclosure relates to methods and structures directed to an IC structure having advanced packaging structure, such as a three-dimensional IC (3DIC) structure, and a method making the same. The 3DIC structures are IC structures having a plurality of IC chips stacked and configured in a same packaging with various configurations, such as a heterogenous integration that includes logic devices stacked over memory devices, or vice versa, for example. In some embodiments, the IC structure includes a transistor structure having multiple vertically stacked transistors, each of which includes multiple vertically stacked nanowires or nanosheets as channels, and a gate structure wrapping around each of the channels. More particularly, the disclosed IC packaging structure includes a mechanism and structure configured for self-cooling.

The disclosed IC packaging structure is integrated with a thermoelectric self-cooling device (TESCD). The thermoelectric self-cooling device includes various structure features and fabrication steps to provide collective thermal dissipation and enhance the thermal performance of the IC packaging structure. In some embodiments, the disclosed IC packaging structure includes a thermoelectric cooling device integrated with a generator and mechanism of utilizing a liquid to transfer heat. Furthermore, the TESCD further includes a mechanism to generate power to self-supply to the thermoelectric cooling (TEC) device, therefore being referred to as thermoelectric self-cooling device. An enhanced liquid cooling solution combined with a self-cooling thermoelectric cooler is provided for high performance chip package. The disclosed device structure and the method making the same provide more efficient heat dissipation and enhance the performance of the packaged IC structure.

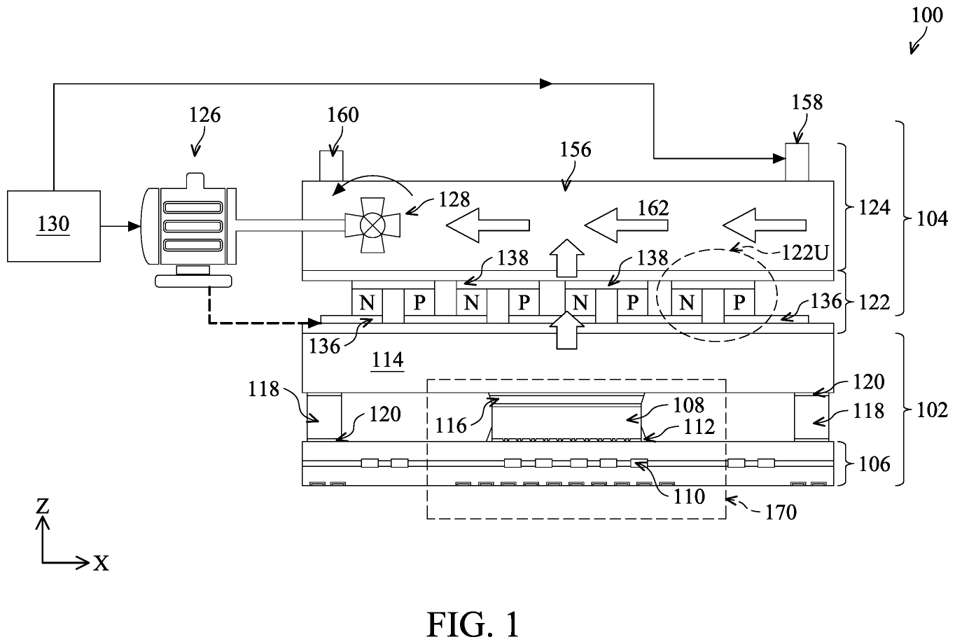

FIG. 1 is a schematic view of an IC structure 100 constructed according to some embodiments. The IC structure 100 includes one or more IC chips formed and sealed in a same packaging and integrated with a thermoelectric self-cooling device. Particularly, the IC structure 100 includes an IC packaging structure 102 and a TESCD 104 formed and secured on the IC packaging structure 102. The IC structure 100, including the IC packaging structure 102 and the TESCD 104, may be attached to a circuit board, such as a printed circuit board (PCB) with proper electrical routing and connection.

The substrate 106 may further include some conductive traces 110 to provide electrical connections, such as connections from the IC chip(s) to the PCB. In some embodiments, the conductive traces 110 in the carrier substrate 106 may include a redistribution layer structure, an interposer, or a combination thereof.

In the disclosed embodiments, the IC packaging structure 102 includes a substrate 106, such as a carrier substrate, and one or more IC chips 108 formed on the substrate 106. Even though FIG. 1 only illustrates one IC chip 108 but it is understood that the IC structure 100 may include two or more IC chips 108 configured on the substrate 106 in a three-dimensional (3D) packaging. In various embodiments, those IC chips may be stacked, directly attached to the substrate 106 side by side, or a combination thereof with a hybrid structure. For example, one or more subset of IC chips 108 are stacked, and one or more subset of IC chips 108 stands alone and is directly attached to the substrate. The IC chips 108 attached to the substrate 106 maybe bonded through any proper mechanism. Various bonding mechanisms can be implemented in multichip package, such as electrically conductive bumps 112 (e.g., metal bumps), through semiconductor vias (TSVs), bonding pads, or combinations thereof. In some embodiments, electrically conductive bumps 112 that connect chips and/or chip stacks to the substrate 106 may be micro-bumps, or controlled collapse chip connections (referred to as C4 bonds) (e.g., solder bumps and/or solder balls). In some embodiments, a under filling material may be filled in the gaps in the bonding interface.

The IC packaging structure 102 further includes a heat spreader 114 of a material with higher thermally conductivity so that to spread heat. The heat spreader 114 may be thermally anisotropic, such as having a lateral thermal conductivity greater than a vertical thermal conductivity so that to be more effectively spreading heat laterally. In some embodiments, the heat spreader 114 includes a metal, or a metal alloy, such as aluminum, copper, steal, or other proper metal/metal alloy. A thermal interface material (TIM) 116 is interposed between the heat spreader 114 and the IC chip(s) 108 to provide thermal dissipation path. The TIM 116. In some embodiments, the TIM 116 includes adhesive material so that the heat spreader 114 is attached to the IC chip(s) 108 through the TIM 116. In furtherance of the embodiments, the TIM 116 includes an adhesive material disposed with a thermal conductive material (such as metal particles, metal filaments, or graphite. In some embodiments, the heat spreader 114 also functions as a lid secured on the substrate 106 to form a metal house as a 3DIC packaging. For example, the IC packaging structure 102 includes an edge frame 118; and the heat spreader 114 is attached to the substrate 106 through the edge frame 118 and an adhesive material 120 applied to an interface between the edge frame 118 and the heat spreader 114 and an interface between the edge frame 118 and the substrate 106. In this case, a cure process may be implemented to the adhesive material 120 for bonding effect, such as through ultraviolet (UV) and mechanical stress.

Still referring to FIG. 1, the TESCD 104 includes a thermoelectric cooling (TEC) device 122 having plurality of TEC units 122U configured in an array to provide thermal cooling effect for the IC chip(s) 108 and reduce the heat generated from the IC chip(s) 108. The TESCD 104 further includes a liquid cooling module 124 and a generator 126 integrated with the TEC device 122. It should be noted that multiple generators 126 and multiple cooling liquid driving devices 128 may be adopted for redundancy, thereby reducing the possibility of insufficient power for driving the TEC device 122.

The cooling liquid driving device 128 includes a mechanism to be driven by a cooling liquid to generate power. In some embodiments, the cooling liquid driving device 128 includes one or more fans, blades, rotors, other suitable cooling liquid driving device or a combination thereof. The cooling liquid driving device 128 is alternatively referred to as the fan 128 without limitation of the scope. The generator 126 and the cooling liquid driving device 128 coupled to generate electrical power and therefore are collectively referred to as an electricity-generating module (or device).

The thermoelectric cooling device 122 uses the Peltier effect to create a heat flux at the junction of two different types of materials. A Peltier thermoelectric heat pump is a solid-state active heat pump which transfers heat from one side of the device to the other, with consumption of electrical energy, depending on the direction of the current. Such an instrument is also called a thermoelectric cooler (TEC) or a TEC device 122. In the present disclosure, TEC device 122 is used for cooling function, therefore transferring the heat from the IC chip(s) 108 to the environment through the thermal interface material 116 and the heat spreader 114, as illustrated by arrows in FIG. 1.

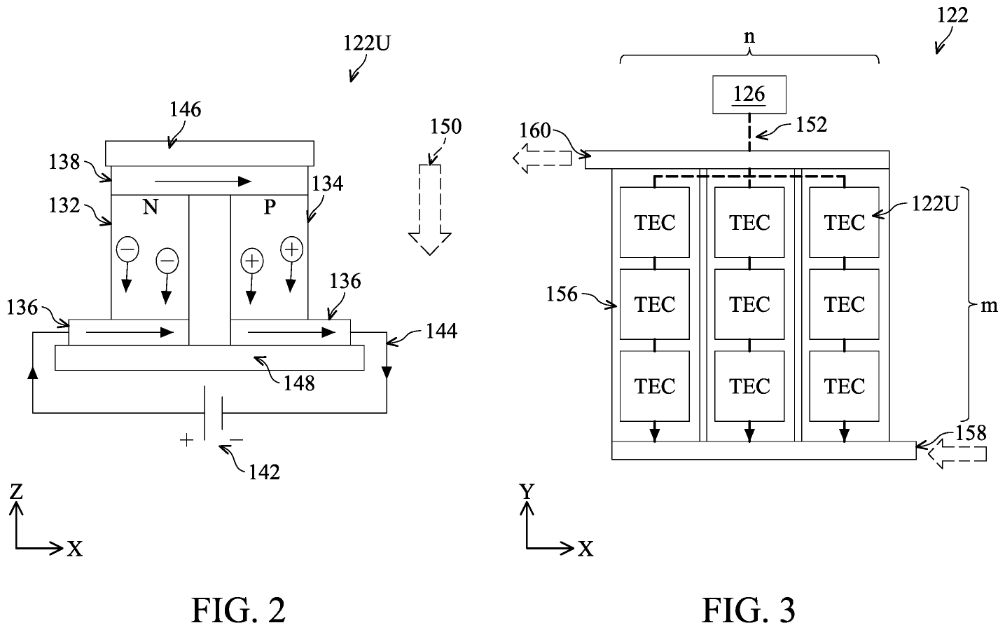

A TEC device 122 includes multiple TEC units 122U configured in proper connection such as in series, in parallel or a combination thereof. Each TEC unit 122U is further described in detail with reference to FIG. 2. FIG. 2 is a schematic or a sectional view of a TEC unit 122U constructed in accordance with some embodiments. The TEC unit 122U includes an n-type doped semiconductor feature 132 and a p-type doped semiconductor feature 134 configured next to each other; bottom conductive features 136 and top conductive features 138; and an electrical power supply 142 (such as a direct-current power or DC power) connected into an electrical loop 144 so that an electrical current flows in the electrical loop 144. When the electrons in the n-type doped semiconductor feature 132 and the holes in the p-type doped semiconductor features 134 are both from a first plate 146 to a second plate 148 along a direction 150. Accordingly, those electrons and holes carry and transfer the thermal energy from the first plate 146 to the second plate 148, thereby providing a cooling effect to the first plate 146. The first plate 146 serves as a cooling surface. Both plates 146 and 148 are thermal conductive to provide a thermal path to dissipate the heat from the first plate 146 to the second plate 148. In some embodiments, the plates 146 and 148 are made of proper thermal conductive material, such as a thermal interface material (TIM). In furtherance of embodiments, the TIM may include an adhesive material dispersed with thermal conductive particles or filaments. The n-type doped semiconductor feature 132 and the p-type doped semiconductor feature 134 are made of one or more semiconductor material (such as silicon, germanium, silicon germanium, other suitable semiconductor material or a combination thereof) doped with a n-type dopant (such as phosphorous) and a p-type dopant (such as boron), respectively. In some embodiments, the n-type doped semiconductor feature 132 and the p-type doped semiconductor feature 134 are formed on a silicon substrate. Alternatively, the n-type doped semiconductor feature 132 and the p-type doped semiconductor feature 134 are formed a procedure that includes deposition using a proper method, such as chemical vapor deposition (CVD); doping by implantation or diffusion; and patterning by lithography process.

The TEC device 122 with multiple TEC units 122U are further described with reference to FIG. 3. FIG. 3 is a top view or a schematic view of the TEC device 122 constructed according to some embodiments. The TEC units 122U are configured into an array with proper electrical connections 152 and are connected to a power supply from a generator 126, as illustrated in FIG. 3. The TEC units 122U in the TEC device 122 are configured in a two-dimensional array, such as n column and m rows. The parameters n and m are any suitable integers. In the disclosed embodiments, n=m=3. However, it is understood that n and m may be different and may take any proper integers. For example, n=4 and m=5. The TEC units 122U are electrically connected in series, in parallel or a combination thereof. In the disclosed embodiments, the TEC units 122U in each column are electrically connected in series. A column of the TEC units 122U is electrically connected with other columns of the TEC units 122 in parallel.

The TEC device 122 are further integrated with a liquid cooling module 124 that includes liquid channels 156, a liquid inlet 158, and a liquid outlet 160 configured to circulate the cooling liquid (or simply liquid) and transfer the heat from the IC structure to the environment. The liquid used in the liquid cooling module 124 may be any suitable liquid compatible with the IC structure 100, such as water, deionized water. In some embodiments, the liquid used in the liquid cooling module 124 may include a gas, such as nitrogen or argon, other suitable gas or a combination thereof. The liquid cooling module 124 and the generator 126 will be further described in detail with reference to FIG. 1.

Referring back to FIG. 1, the TESCD 104 includes the TEC device 122, the liquid cooling module 124 and the generator 126 integrated together. The liquid cooling module 124 is coupled with the TEC device 122 to remove the heat generated from the IC chip(s) 108.

The TESCD 104 further includes one or more cooling liquid driving device 128 configured in the liquid cooling module 124. For example, the cooling liquid driving device 128 includes a fan and is configured in the liquid channels 156 and driven by the flowing liquid, such as flowing along a direction 162 from the liquid inlet 158 to the liquid outlet 160 and driving the cooling liquid driving device 128. The fan 128 is further coupled to the generator 126 to generate electrical power under the driving force of the flowing liquid in the liquid channels 156. In the disclosed embodiments, the fan 128 is configured substantially perpendicular to the flowing direction 162 of the liquid to effectively generate electricity power. Particularly, the rotation axis of the fan 128 is configured perpendicular to the flowing direction 162 of the liquid.

The generator 126, as coupled with the cooling liquid driving device 128, generate electrical power. For example, the rotations of the cooling liquid driving device 128 drive the generator 126 to generate the electrical power, which is supplied to the TEC device 122 to enable the thermal dissipation. Thus, the TEC device 122 is able to operate without external power source, thereby saving energy and cost. Accordingly, the TESCD 104 is self-supported or self-cooling.

The generator 126 is a device that converts motion-based power into electric power for use in an external circuit. Sources of mechanical energy include gas turbines, liquid turbines, or other suitable mechanism. The generator 126 shown in FIG. 1 is only a schematic illustration. The generator 126 may have any suitable structure and may include any suitable generator.

The cooling liquid driving device 128 is a mechanic device that is able to be driven by the flow of the liquid flowing in the liquid channels 156. The cooling liquid driving device 128 in FIG. 1 is only schematic view for illustration. The cooling liquid driving device 128 can have any suitable structure. In some embodiments, the cooling liquid driving device 128 is a turbine, a blade, a rotor or a combination thereof. The cooling liquid driving device 128 is properly configured in the liquid channels 156 to maximize the mechanical power to the cooling liquid driving device 128 from the flow liquid, as illustrated in FIG. 1.

In some embodiments, the TESCD 104 further includes a controller 130 coupled with the generator 126 and the liquid inlet 158 (such as a valve of the liquid inlet) to monitor and control the flow rate or flow speed, thereby adjusting the voltage (or current) supplied to the TEC device 122. Thus, the voltage/current supplied to the TEC device 122 is monitored and controlled by adjusting the flow speed of the cooling liquid so as to keep the TEC device 122 under proper operating condition.

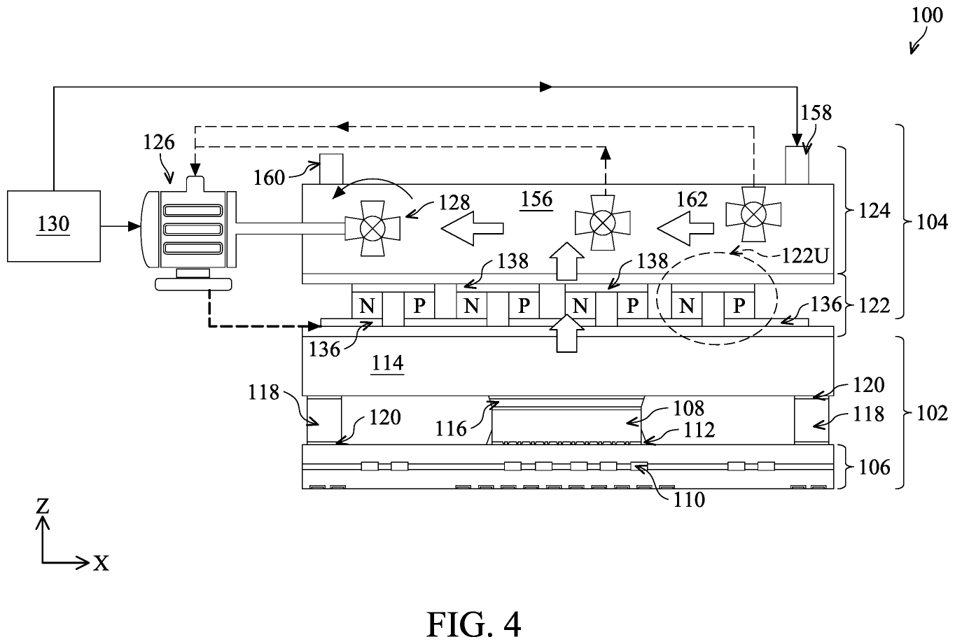

FIG. 4 is a sectional view or schematic view of the IC structure 100 constructed according to some embodiments. The IC structure 100 in FIG. 4 is similar to the IC structure 100 in FIG. 1. However, the TESCD 104 includes a plurality of fans 128 configured in the liquid channels 156, such as three fans 128 illustrated in FIG. 4 as an example. The number of the fans 128 and positions configured in the liquid channels 156 are optimized to maximize the power output. In the disclosed embodiments, the fans 128 are configured perpendicular to the flowing direction 162 of the liquid to effectively generate the electrical power.

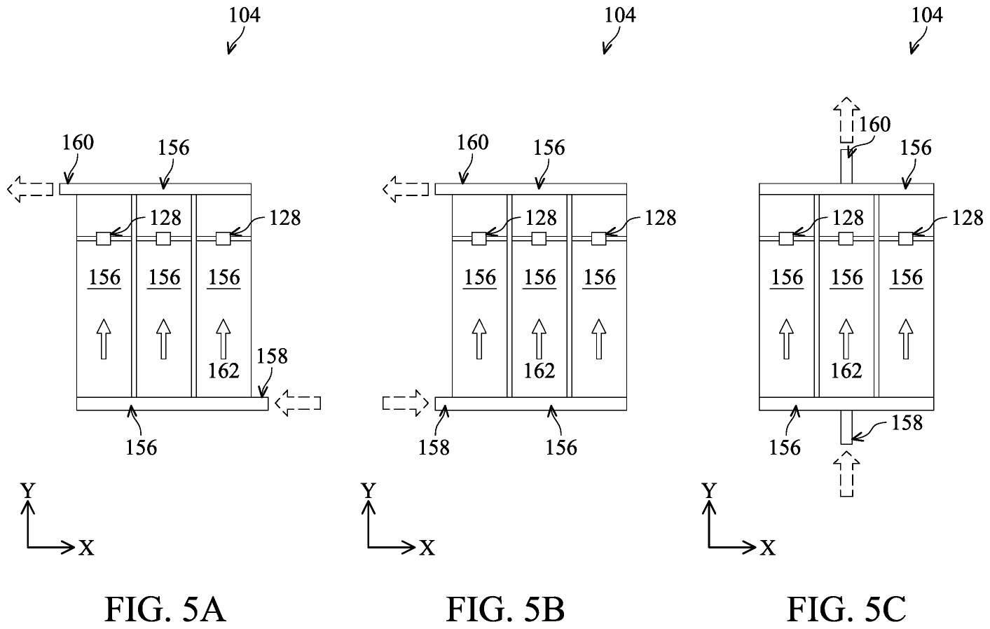

The liquid cooling module may be designed with different configuration as illustrated in FIGS. 5A through 5C. FIGS. 5A through 5C are top views of the TESCD 104, in portion, constructed in accordance with some embodiments. Especially, the liquid cooling module 124 is illustrated in various configurations. In FIG. 5A, the liquid channels 156 are designed in Z-shaped configuration and the fans 128 are configured in the liquid channels 156. Thus, the liquid inlet 158 and the liquid outlet 160 are configured in diagonal corners. The liquid flows from the liquid inlet 158 along −X direction, then flows through the fans 128 along Y direction, and then flows to the liquid outlet 160 along −X direction.

In FIG. 5B, the liquid channels 156 are designed in C-shaped configuration and the fans 128 are configured in the liquid channels 156. Thus, the liquid inlet 158 and the liquid outlet 160 are configured on same size corners. The liquid flows from the liquid inlet 158 along X direction, then flows through the fans 128 along Y direction, and then flows to the liquid outlet 160 along −X direction.

In FIG. 5C, the liquid channels 156 are designed in I-shaped configuration and the fans 128 are configured in the liquid channels 156. Thus, the liquid inlet 158 and the liquid outlet 160 are configured on center locations of opposite sides. The liquid flows toward edges from the liquid inlet 158, then flows through the fans 128 along Y direction, and then flows toward the center to the liquid outlet 160.

The liquid cooling module 124 may be designed with other configuration According to some embodiments. It is understood that the liquid inlet 158, the liquid outlet 160 and the liquid channels 156 may be adjusted so that the flow directions of the liquid are different.

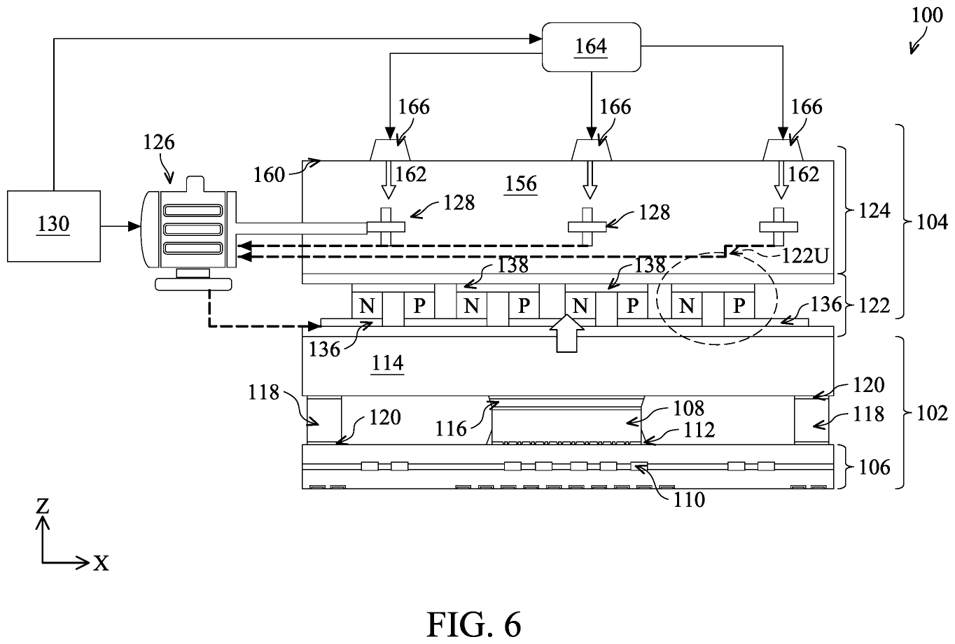

FIG. 6 is a sectional view or schematic view of the IC structure 100 constructed according to some embodiments. The IC structure 100 in FIG. 6 is similar to the IC structure 100 in FIG. 1. However, the TESCD 104 includes a jet impingement system 164 and nozzles 166 configured in the liquid cooling module 124. The Jet impingement system 164 provides fluid to the liquid channels 156 through the nozzles 166. The nozzles 166 are configured on top of the respective fans 128. For example, the TESCD 104 includes a number (such as 3, 4, or 5) of fans 128, the same number of the nozzles 166 are configured over the fans 128 and coupled to the jet impingement system 164 to provide liquid flowing through the fans 128 in the liquid channels 156.

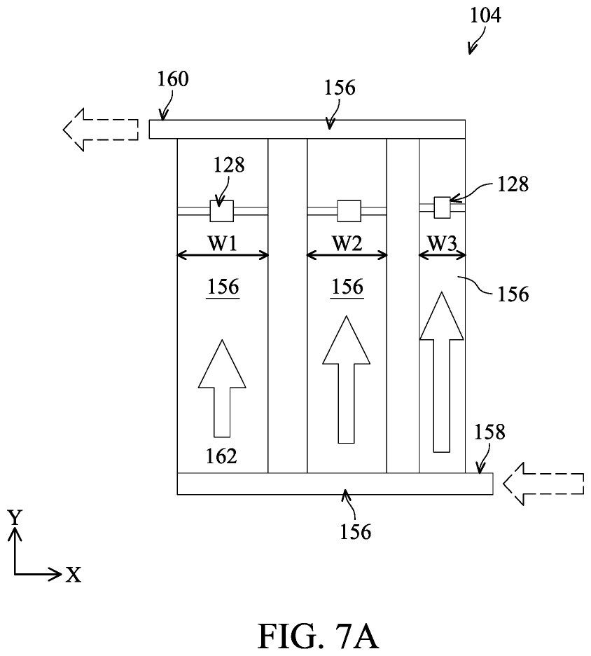

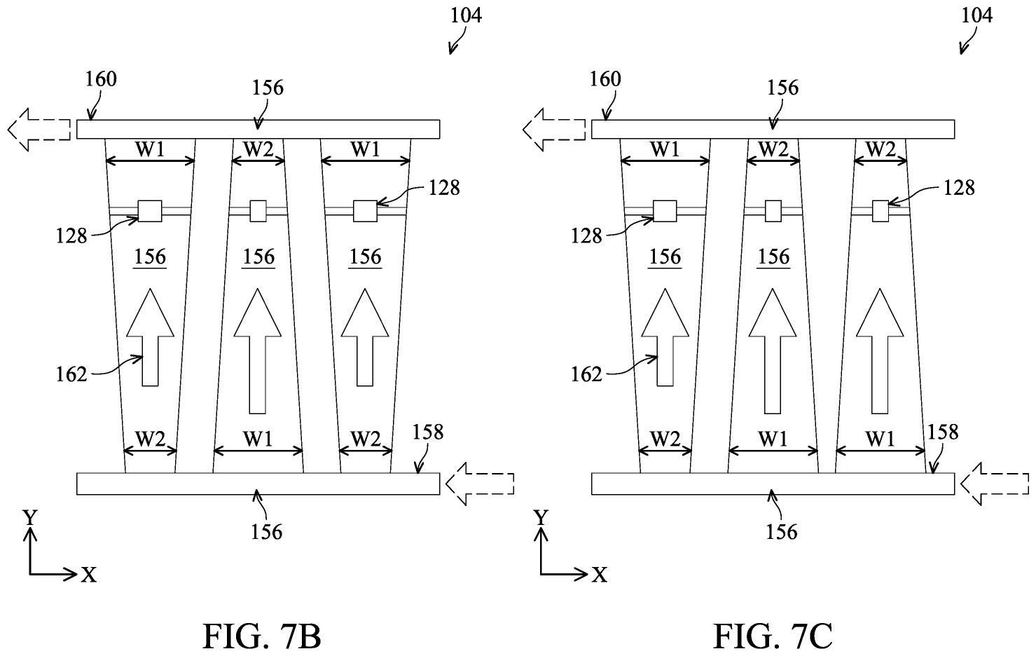

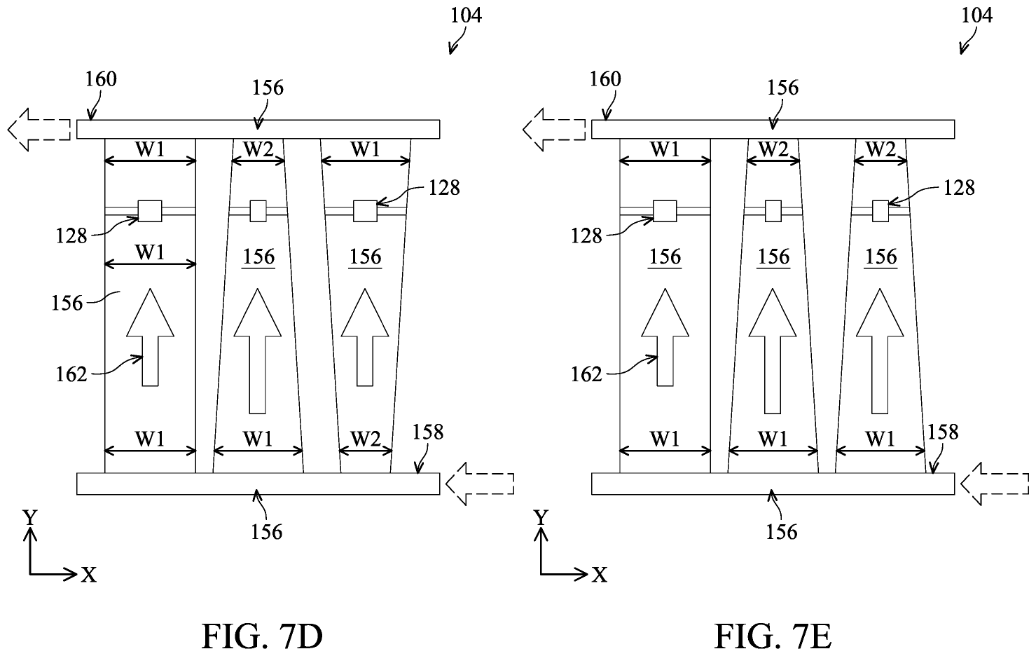

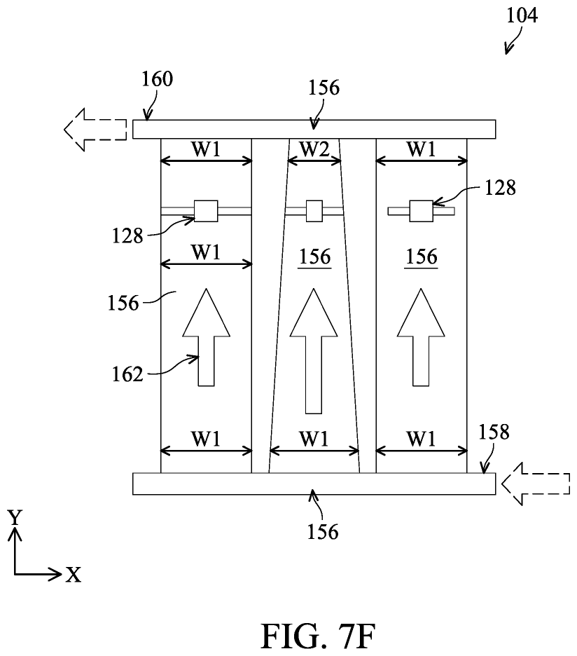

FIGS. 7A through 7E are top views of the TESCD 104, in portion, constructed in accordance with various embodiments. Especially, the liquid cooling module 124 is designed differently in terms of dimensions and shapes to control and tune the flow speed of the cooling liquid.

In FIG. 7A, the liquid channels 156 are designed with different dimensions, such as different widths. The width (i.e., cross-sectional size) of the liquid channels 156 are designed differently so as to control the flow speed of the cooling liquid, which is related to the performance of the cooling liquid driving device 128 in the liquid channel 156. For example, when the width of a liquid channel 156 is reduced, the liquid flows faster therein, and the more electricity power is generated by the fan 128 and the generator 126. Therefore, higher power is supplied to the TEC device 122, enhancing the thermal-dissipation capacity of the TESCD 104. Accordingly, the flow speed in each liquid channel 156 can be controlled independently, which help to resolve the local hotspot issue. Note that the numeral 162 indicates the flow direction and its size also represents the flow speed.

There are a number of liquid channels 156 along Y direction from the liquid inlet 158 to the liquid outlet 160. As each Y direction liquid channel 156 configured differently relative to the liquid inlet 158 and the liquid outlet 160, the widths are designed differently to tune liquid speed and output power from each fan 128, so to maximize the total output power, optimize the thermal dissipation through the liquid or both. In the disclosed embodiments, there three Y direction liquid channels 156 and three fans 128 configured to those Y direction liquid channels 156, respectively. It is understood that the number of the fans 128 (or the number of the Y direction liquid channels 156) can be any proper number, such as 4, 5, 6 or other suitable number, depending on the design. Each Y direction liquid channels 156 includes a fan configured therein. Especially, the corresponding fan is configured with its rotation axis along Z direction that is perpendicular to X and Y directions. In the present embodiments, the widths of the Y direction liquid channels 156 are W1, W2 and W3, respectively. In furtherance of the embodiment, W1>W2>W3. In some embodiments, a ratio r of W1/W2=W2/W3. In the disclosed examples, the ratio r ranges between 1.2 and 1.6.

In some embodiments, the shapes of the liquid channels 156 are tuned to control and tune the flow speed of the cooling liquid, as illustrated in FIGS. 7B through 7F. Especially, the experiments and analysis found that the varying the cross-sectional areas of the liquid channels 156 along the flow direction can change the flow speed of the cooling liquid. Furthermore, decreasing the cross-sectional area of one liquid channel 156 along the flow direction of the cooling liquid can increase the flow speed; and increasing the cross-sectional area of one liquid channel 156 along the flow direction of the cooling liquid can reduce the flow speed. Tuning the flow speeds of various liquid channels 156 of the liquid cooling module 124 can further tune flow pattern, maximize the TEC cooling capacity, and enhance the power generation by the cooling liquid driving devices 128. Furthermore, the flow speed in each liquid channel 156 can be controlled independently, which help to resolve the local hotspot issue, where more cooling power is needed.

In FIG. 7B, the liquid channels 156 are designed with different shapes, such as trapezoids. The liquid cooling module 124 includes three liquid channels 156 configured in parallel and with varying cross-sectional area. Especially, the first liquid channel 156 includes the cross-sectional size increased along the flow direction from W2 to W1 and therefore has a reduced flow speed; the second liquid channel 156 includes the cross-sectional size decreased along the flow direction from W1 to W2 and therefore has an increased flow speed; and the third liquid channel 156 includes the cross-sectional size increased along the flow direction from W2 to W1 and therefore has a reduced flow speed. In some embodiments, a ratio r of W1/W2 ranges between 1.2 and 1.6.

In FIG. 7C, the liquid channels 156 are designed with different shapes, such as trapezoids. The liquid cooling module 124 includes three liquid channels 156 configured in parallel and with varying cross-sectional area. Especially, the first liquid channel 156 includes the cross-sectional size increased along the flow direction from W2 to W1 and therefore has a reduced flow speed; the second liquid channel 156 includes the cross-sectional size decreased along the flow direction from W1 to W2 and therefore has an increased flow speed; and the third liquid channel 156 includes the cross-sectional size decreased along the flow direction from W1 to W2 and therefore has a increased flow speed. In some embodiments, a ratio r of W1/W2 ranges between 1.2 and 1.6.

In FIG. 7D, the liquid channels 156 are designed with different shapes, such as trapezoids and rectangles. The liquid cooling module 124 includes three liquid channels 156 configured in parallel. Especially, the first liquid channel 156 has a rectangle shape and includes the cross-sectional size as a constant W1 along the flow direction; the second liquid channel 156 has a trapezoid shape with the cross-sectional size decreased along the flow direction from W1 to W2 and therefore has an increased flow speed; and the third liquid channel 156 has a trapezoid shape with the cross-sectional size increased along the flow direction from W2 to W1 and therefore has a reduced flow speed. In some embodiments, a ratio r of W1/W2 ranges between 1.2 and 1.6.

In FIG. 7E, the liquid channels 156 are designed with different shapes, such as trapezoids and rectangles. The liquid cooling module 124 includes three liquid channels 156 configured in parallel. Especially, the first liquid channel 156 has a rectangle shape and includes the cross-sectional size as a constant W1 along the flow direction; the second liquid channel 156 has a trapezoid shape with the cross-sectional size decreased along the flow direction from W1 to W2 and therefore has an increased flow speed; and the third liquid channel 156 has a trapezoid shape with the cross-sectional size decreased along the flow direction from W1 to W2 and therefore has an increased flow speed. In some embodiments, a ratio r of W1/W2 ranges between 1.2 and 1.6.

In FIG. 7F, the liquid channels 156 are designed with different shapes, such as trapezoids and rectangles. The liquid cooling module 124 includes three liquid channels 156 configured in parallel. Especially, the first liquid channel 156 has a rectangle shape and includes the cross-sectional size as a constant W1 along the flow direction; the second liquid channel 156 has a trapezoid shape with the cross-sectional size decreased along the flow direction from W1 to W2 and therefore has an increased flow speed; and the third liquid channel 156 has a rectangle shape with the cross-sectional size as a constant W1 along the flow direction. In some embodiments, a ratio r of W1/W2 ranges between 1.2 and 1.6.

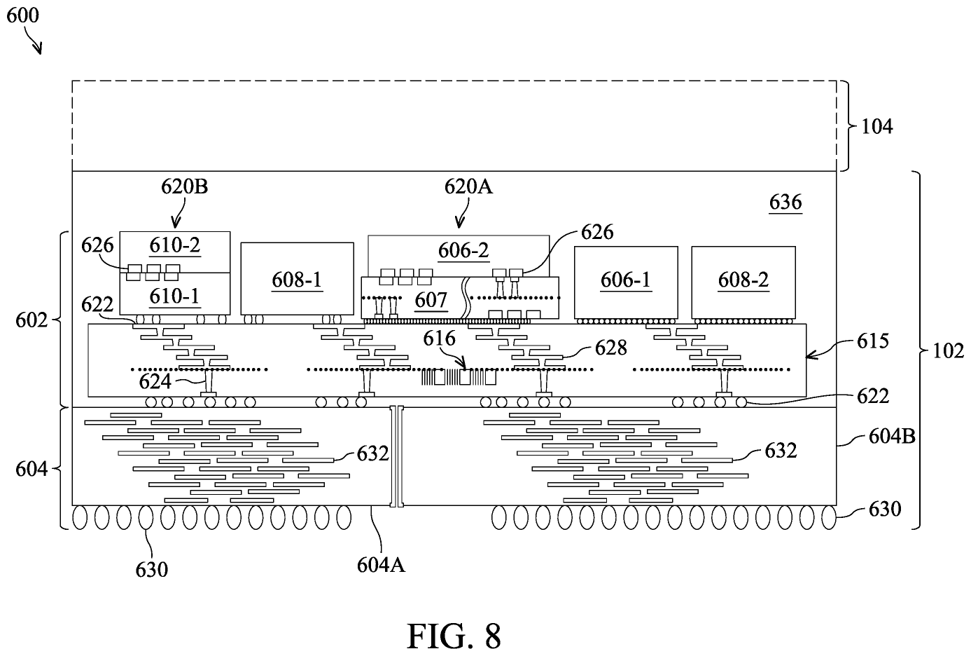

Referring back to FIG. 1, the IC packaging structure 102 may include multiple IC chips 108 in any suitable configuration and sealed in the same packaging structure. For example, a portion of the IC packaging structure 102 in a dashed box 170 in FIG. 1 is further described according to various embodiments with reference to FIG. 8.

FIG. 8 is a fragmentary cross-sectional view of the IC structure 600, in portion or entirety, that is provided by arranging a chipset using a combination of multichip packaging technologies, such as chip-on-wafer-on-substrate (CoWoS) packaging technology, system-on-integrated-chips (SoIC) multi-chip packaging technology, an integrated-fan-out (InFO) package, according to various aspects of the present disclosure. Particularly, the IC structure 600 includes an IC packaging structure 102 and a TESCD 104 attached to the IC packaging structure 102 to provide self-cooling effect. The TESCD 104 is described above in FIG. 1. However, the IC packaging structure 102 is different according to various embodiments, The IC structure shown in FIG. 8 is to illustrate that the TESCD 104 can be used to any suitable IC packaging structure 102 to provide self-cooling effect. The IC structure 600, which can be referred to as a 3D IC package and/or a 3D IC module, includes a CoW structure 602 attached to a substrate 604 (e.g., a package substrate), which includes a package component 604A and a package component 604B in the depicted embodiment. CoW structure 602 includes a chipset (e.g., a core chip 606-1, a core chip 606-2, photonic chip 607, a memory chip 608-1, a memory chip 608-2, an input/output (I/O) chip 610-1, and an I/O chip 610-2 electrically connected to each other) attached to an interposer 615. The chipset is arranged into at least one chip stack, such as a chip stack 620A and a chip stack 620B. Chip stack 620A includes core chip 606-2 and photonic chip 607, and chip stack 620B includes I/O chip 610-1 and I/O chip 610-2. In the depicted embodiment, chips of chip stack 620A and chip stack 620B are directly bonded face-to-face and/or face-to-back to provide SoIC packages of multichip package. In some embodiments, a chip stack of multichip package includes a combination of chip types, such as a core chip having one or more memory chips disposed thereover. FIG. 8 has been simplified for the sake of clarity to better understand the inventive concepts of the present disclosure. Additional features can be added in multichip package, and some of the features described below can be replaced, modified, or eliminated in other embodiments of multichip package.

Core chip 606-1 and core chip 606-2 are central processing unit (CPU) chips and/or other chips. In some embodiments, core chip 606-1 is a CPU chip that forms at least a portion of CPU cluster, and core chip 606-2 is a GPU chip. In some embodiments, core chip 606-1 and core chip 606-2, or combinations thereof represent a stack of CPU dies, which can be bonded and/or encapsulated in a manner that provides a CPU package and/or a CPU-based SoIC package. In some embodiments, core chip 606-1 and core chip 606-2, or combinations thereof represent a stack of dies, which can be bonded and/or encapsulated in a manner that provides a GPU package and/or a SoIC package (e.g., a GPU-based SoIC package). In some embodiments, core chip 606-1, core chip 606-2, or combinations thereof represent a stack of CPU dies, which can be bonded and/or encapsulated in a manner that provides a core package and/or a core-based SoIC package. In some embodiments, core chip 606-1, core chip 606-2, or combinations thereof are SoCs.

Memory chip 608-1 and memory chip 608-2 are high bandwidth memory (HBM) chips, a graphics double-data rate (GDDR) memory chips, dynamic random-access memory (DRAM) chips, static random-access memory (SRAM) chips, magneto-resistive random-access memory (MRAM) chips, resistive random-access memory (RRAM) chips, other suitable memory chips, or combinations thereof. In some embodiments, memory chip 608-1 and memory chip 608-2 are HBM chips that form at least a portion of the memory device. In some embodiments, memory chip 608-1 and memory chip 608-2 are a GDDR memory chips that form at least a portion of the memory device. In some embodiments, memory chip 608-1 is an HBM chip and memory chip 608-2 is a GDDR memory chip, or vice versa, that form at least a portion of the memory device. In some embodiments, memory chip 608-1 and/or memory chip 608-2 represent a stack of memory dies, which can be bonded and/or encapsulated in a manner that provides a memory package and/or a memory-based SoIC package. The memory package may be an HBM package (also referred to as an HBM cube) or a GDDR memory package.

Core chip 606-1, core chip 606-2 and photonic chip 607 (and thus chip stack 620A), memory chip 608-1, memory chip 608-2, and I/O chip 610-1 and I/O chip 610-2 (and thus chip stack 620B) are attached and/or interconnected to interposer 615. Interposer 615 is attached and/or interconnected to substrate 604. Various bonding mechanisms can be implemented in multichip package, such as electrically conductive bumps 622 (e.g., metal bumps), through semiconductor vias (TSVs) 624, bonding pads 626, or combinations thereof. For example, electrically conductive bumps 622 physically and/or electrically connect core chip 606-1, photonic chip 607 (and thus chip stack 620A), memory chip 608-1, memory chip 608-2, and I/O chip 610-1 (and thus chip stack 620B) to interposer 615. Electrically conductive bumps 622 and TSVs 624 physically and/or electrically connect interposer 615 to substrate 604. TSVs 624 of interposer 615 are electrically connected to electrically conductive bumps 622 of chips and/or chip stacks of CoW structure 602 through electrically conductive routing structures (paths) 628 of interposer 615. Bonding pads 626 physically and/or electrically connect photonic chip 607 and core chip 606-2 of chip stack 620A and I/O chip 610-1 and I/O chip 610-2 of chip stack 620B. Also, dielectric bonding layers adjacent to bonding pads 626 can physically contact photonic chip 607 and core chip 606-2 of chip stack 620A and/or I/O chip 610-1 and I/O chip 610-2 of chip stack 620B. In some embodiments, electrically conductive bumps 622 that connect chips and/or chip stacks to interposer 615 may be micro-bumps, while electrically conductive bumps 622 that connect interposer 615 to substrate 604 may be controlled collapse chip connections (referred to as C4 bonds) (e.g., solder bumps and/or solder balls).

In some embodiments, substrate 604 is a package substrate, such as coreless substrate or a substrate with a core, that may be physically and/or electrically connected to another component by electrical connectors 630. Electrical connectors 630 are electrically connected to electrically conductive bumps 622 of interposer 615 through electrically conductive routing structures (paths) 632 of substrate 604. In some embodiments, package component 604A and package component 604B are portions of a single package substrate. In some embodiments, package component 604A and package component 604B are separate package substrates arranged side-by-side. In some embodiments, substrate 604 is an interposer. In some embodiments, substrate 604 is a printed circuit board (PCB).

In some embodiments, interposer 615 is a semiconductor substrate, such as a silicon wafer (which may generally be referred to as a silicon interposer). In some embodiments, interposer 615 is laminate substrate, a cored package substrate, a coreless package substrate, or the like. In some embodiments, interposer 615 can include an organic dielectric material, such as a polymer, which may include polyimide, polybenzoxazole (PBO), benzocyclobutene (BCB), other suitable polymer-based material, or combinations thereof. In some embodiments, redistribution lines (layers) (RDLs) can be formed in interposer 615, such as within the organic dielectric material(s) of interposer 615. RDLs may form a portion of electrically conductive routing structures 628 of interposer 615. In some embodiments, RDLs electrically connect bond pads on one side of interposer 615 (e.g., top side of interposer 615 having chipset attached thereto) to bond pads on another side of interposer 615 (e.g., bottom side of interposer 615 attached to substrate 604). In some embodiments, RDLs electrically connect bond pads on the top side of interposer 615, which may electrically connect chips of the chipset. In the disclosed embodiment, one or more deep trench capacitor 616 may be embedded in interposer 615.

In some embodiments, multichip package can be configured as a 2.5D IC package and/or a 2.5D IC module by rearranging the chipset, such that each chip is bonded and/or attached to interposer 615. In other words, the 2.5D IC module does not include a chip stack, such as chip stack 620A and chip stack 620B, and chips of the chipset are arranged in a single plane. In such embodiments, core chip 606-2 and I/O chip 610-2 are electrically and/or physically connected to interposer by electrically conductive bumps 622.

The IC structure 600 is sealed in a package using a sealing material 636. In the present embodiment, the sealing material 636 includes an anisotropic thermal dissipation material described above. The IC structure 600 with the anisotropic thermal dissipation material in the sealing package provides a mechanism to effectively transfer heat directionally, such as transferring heat horizontally over the substrate 604.

Particularly, the TESCD 104 includes a thermoelectric cooling (TEC) device 122 having plurality of TEC units 122U configured in an array to provide thermal cooling effect for the IC chip(s) 108 and reduce the heat generated from the IC chip(s) 108, as described in FIG. 1. The TESCD 104 further includes a liquid cooling module 124 and a generator 126 integrated with the TEC device 122. In some embodiments, multiple generators 126 and multiple cooling liquid driving devices 128 are adopted for redundancy, thereby reducing the possibility of insufficient power for driving the TEC device 122. The disclosed structure of the TESCD 104 and the method making the same provide more efficient heat dissipation and enhance the performance of the IC structure 600.

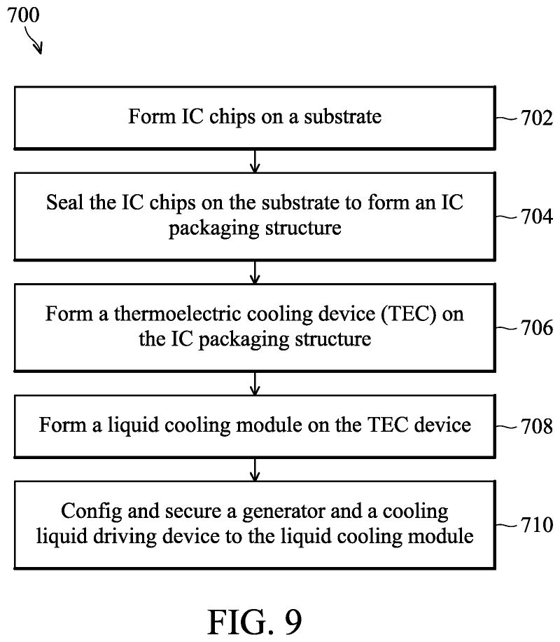

FIG. 9 illustrates a flowchart of method 700 making the IC structure 100 in FIG. 1, in portion, constructed according to various embodiments. The method 700 includes an operation 702 by forming IC chips 108 on a substrate 106, such as bonding the IC chips 108 on the substrate 106. The IC chips 108 may include various IC chips, such as electrical IC chips, memory chips, photonic IC chips, other suitable IC chips or a combination thereof. The IC chips 108 may be properly disposed on the substrate 106 in any proper configurations that include stacked IC chip sets, laterally disposed on the substrate 106 next to each other, and other configuration as illustrated in FIGS. 1 and 8.

The method 700 includes an operation 704 by sealing the IC chips 108 on the substrate 106 to form an IC packaging structure 102. The IC chips 108 are enclosed by the substrate 106 and the sealing structure with intended sealing effect. In some embodiments, the sealing structure may include a heat spreader 114, a thermal interface material (TIM) 116, an edge frame 118, other suitable components configured to form an enclosed structure to provide sealing effect and provide thermal dissipation paths to transfer heat from the IC chips 108.

The method 700 includes an operation 706 by forming a thermoelectric cooling (TEC) device 122 on the IC packaging structure 102, such as attached or bonded to the IC packaging structure 102. The TEC device 122 includes a plurality of TEC units 122U configured in an array to provide thermal cooling effect for the IC chip(s) 108 and reduce the heat generated from the IC chip(s) 108.

The method 700 includes an operation 708 by forming a liquid cooling module 124 on the TEC device 122. The liquid cooling module 124 includes liquid channels 156, a liquid inlet 158, and a liquid outlet 160 configured to circulate the cooling liquid (or simply liquid) and transfer the heat from the IC structure to the environment.

The method 700 includes an operation 710 by configuring and securing one or more generator 126 and one or more cooling liquid driving device 128 to the liquid cooling module 124 such that the liquid cooling module 124, the generator 126 and the cooling liquid driving device 128 are integrated with the TEC device 122 for thermoelectric self-cooling. The method 700 may include other operations before, during or after the implementation of the operations described above.

The present disclosure provides an IC structure that including an IC packaging structure having one or more IC chips sealed in the same packaging and a thermoelectric self-cooling device integrated with the IC packaging structure. The thermoelectric self-cooling device (TESCD) includes a thermoelectric cooling (TEC) device having a plurality of TEC units configured in an array and electrically connected to provide cooling effect to the IC chips in the IC packaging structure. The TESCD further include a cooling liquid driving device and a generator coupled with the cooling liquid driving device to collectively generate electrical power supplied to the TEC device so to achieve self-support so self-cooling function.

In one example aspect, the present disclosure provides an integrated circuit (IC) structure. The IC structure includes an IC packaging structure having an IC chip; and a thermoelectric self-cooling device (TESCD) integrated with the IC packaging structure. The TESCD further includes a thermoelectric cooling (TEC) device having a plurality of TEC units configured in an array and electrically connected to provide cooling effect to the IC packaging structure, and a liquid cooling module having a cooling liquid driving device and a generator coupled with the cooling liquid driving device to collectively generate an electrical power supplied to the TEC device with self-cooling function to the IC packaging structure.

In one example aspect, the present disclosure provides an integrated circuit (IC) structure. The IC structure includes an IC packaging structure having an IC chip; and a thermoelectric self-cooling (TESCD) integrated with and providing cooling effect to the IC packaging structure. The TESCD further includes a thermoelectric cooling (TEC) device having a plurality of TEC units configured in an array with n column and m rows, n and m being proper integers, wherein the TEC units in each column are electrically in series and each row of the TEC units are electrically connected with other row in parallel, and a liquid cooling module having a cooling liquid driving device and a generator coupled with the cooling liquid driving device to collectively generate an electrical power supplied to the TEC device with self-cooling function to the IC packaging structure.

In one example aspect, the present disclosure provides a method making an integrated circuit (IC) structure. The method includes forming an integrated circuit (IC) chip on a substrate; sealing the IC chip on the substrate, thereby forming an IC packaging structure; forming a thermoelectric cooling (TEC) device on the IC packaging structure and having a plurality of TEC units configured in an array; and forming a liquid cooling module on the TEC device and integrated with the TEC device to provide thermal cooling effect to the IC chip.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. An integrated circuit (IC) structure, comprising:
an IC packaging structure having an IC chip; and
a thermoelectric self-cooling device (TESCD) integrated with the IC packaging structure, wherein the TESCD further includes:
a thermoelectric cooling (TEC) device having a plurality of TEC units configured in an array and electrically connected to provide cooling effect to the IC packaging structure, and
a liquid cooling module having a cooling liquid driving device and a generator coupled with the cooling liquid driving device to collectively generate an electrical power supplied to the TEC device with self-cooling function to the IC packaging structure.

2. The IC structure of claim 1, wherein the liquid cooling module further includes
liquid channels with the cooling liquid driving device configured therein;
a liquid inlet coupled to the liquid channels to provide a cooling liquid; and
a liquid outlet coupled to the liquid channels for exhausting the cooling liquid.

3. The IC structure of claim 2, wherein the TESCD further includes a controller coupled with the cooling liquid driving device and the generator to control a flow speed of the cooling liquid in the liquid channels, thereby adjusting the electrical power supplied to the TEC device.

4. The IC structure of claim 2, wherein the liquid cooling module further includes
a jet impingement system; and
nozzles coupled with the jet impingement system to provide the cooling liquid to the liquid channels.

5. The IC structure of claim 2, wherein the liquid channels include first, second and third liquid channels distanced from each other along a first direction and longitudinally oriented along a second direction perpendicular to the first direction.

6. The IC structure of claim 5, wherein the liquid inlet and the liquid outlet are configured on diagonal corners.

7. The IC structure of claim 5, wherein the liquid inlet and the liquid outlet are distanced along the second direction and are directly connected to the first liquid channel.

8. The IC structure of claim 5, wherein the liquid inlet and the liquid outlet are distanced along the second direction and are directly connected to the second liquid channel.

9. The IC structure of claim 5, wherein the cooling liquid driving device includes first, second and third fans configured in the first, second and third liquid channels, respectively.

10. The IC structure of claim 9, wherein each of the first, second and third fans is configured with a rotation axis perpendicular to the first and second directions.

11. The IC structure of claim 5, wherein
the first liquid channel spans a first width W1 along the first direction;
the second liquid channel spans a second width W2 along the first direction;
the third liquid channel spans a third width W3 along the first direction; and
W1 is greater than W2, and W2 is greater W3.

12. The IC structure of claim 5, wherein
the first liquid channel includes a first constant cross-sectional area along the second direction;
the second liquid channel includes a second cross-sectional area decreased along a flow direction of the cooling liquid; and
the third liquid channel includes a third cross-sectional area increased along the flow direction of the cooling liquid.

13. The IC structure of claim 1, wherein
the TEC units include n*m TEC units configured in the array with n column and m rows, n and m being proper integers;
each column includes m TEC units electrically connected in series; and
each row includes n TEC units electrically connected with other rows in parallel.

14. The IC structure of claim 1, wherein the IC packaging structure further includes
a substrate;
an edge frame configured on the substrate, wherein the IC chip is attached to the substrate; and
a thermal interface material layer and a heat spreader over the thermal interface material layer.

15. The IC structure of claim 14, wherein the IC chip is a first IC chip, where the IC packaging structure further includes
a second IC chip attached to the substrate and next to the first IC chip; and
a third IC chip stacked on and electrically connected to the first IC chip, wherein the first, second and third IC chips are sealed in a same packaging.

16. An integrated circuit (IC) structure, comprising:
an IC packaging structure having an IC chip; and
a thermoelectric self-cooling (TESCD) integrated with and providing cooling effect to the IC packaging structure, wherein the TESCD further includes:
a thermoelectric cooling (TEC) device having a plurality of TEC units configured in an array with n column and m rows, n and m being proper integers, wherein the TEC units in each column are electrically in series and each row of the TEC units are electrically connected with other row in parallel, and
a liquid cooling module having a cooling liquid driving device and a generator coupled with the cooling liquid driving device to collectively generate an electrical power supplied to the TEC device with self-cooling function to the IC packaging structure.

17. The IC structure of claim 16, wherein
the liquid cooling module further includes liquid channels with the cooling liquid driving device configured therein, a liquid inlet coupled to the liquid channels to provide a cooling liquid, and a liquid outlet coupled to the liquid channels for exhausting the cooling liquid, and
the TESCD further includes a controller coupled with the cooling liquid driving device and the generator to control a flow speed of the cooling liquid in the liquid channels, thereby adjusting the electrical power supplied to the TEC device.

18. The IC structure of claim 17, wherein the liquid channels include
the first liquid channel includes a first constant cross-sectional area along a flow direction of the cooling liquid;
the second liquid channel includes a second cross-sectional area decreased along the flow direction of the cooling liquid; and
the third liquid channel includes a third cross-sectional area increased along the flow direction of the cooling liquid.

19. A method, comprising:
forming an integrated circuit (IC) chip on a substrate;
sealing the IC chip on the substrate, thereby forming an IC packaging structure;
forming a thermoelectric cooling (TEC) device on the IC packaging structure and having a plurality of TEC units configured in an array; and
forming a liquid cooling module on the TEC device and integrated with the TEC device to provide thermal cooling effect to the IC chip.

20. The method of claim 19, further comprising configuring and securing a generator and a cooling liquid driving device to the liquid cooling module such that the liquid cooling module, the generator and the cooling liquid driving device are integrated with the TEC device for thermoelectric self-cooling.
